(19) United States
(12) Patent Application Publication
(10) Pub. No.: US 2007/0181879 A1
(43) Pub. Date: Aug. 9, 2007

(54) DISPLAY DEVICE AND MANUFACTURING METHOD THEREOF

(75) Inventor: Dong-won Lee, Seongnam-si (KR)

Correspondence Address: CANTOR COLBURN, LLP, 55 GRIFFIN ROAD SOUTH, BLOOMFIELD, CT, 06002, US

(73) Assignee: SAMSUNG ELECTRONICS CO., LTD.,, Suwon-si (KR)

(21) Appl. No.: 11/671,513

(22) Filed: Feb. 6, 2007

(30) Foreign Application Priority Data
Feb. 6, 2006 (KR) 1020060011218

(51) Int. Cl. H01L 29/04; H01L 21/00

(52) U.S. Cl. 257/59; 257/72; 257/E27.131; 438/48

(57) ABSTRACT

A display device includes a plurality of thin film transistors, a passivation layer formed on the thin film transistors, a pixel electrode formed on the passivation layer and including a rectangular shape and a contact region electrically connected with the thin film transistors, and a wall formed around the pixel electrode, a portion of the wall spaced from the pixel electrode. The contact region is formed along a side of the pixel electrode.

This application claims priority to Korean Patent Application No. 2006-0011218, filed on Feb. 6, 2006, and all the benefits accruing therefrom under 35 U.S.C. §119, the contents of which is incorporated herein by reference in its entirety.

### BACKGROUND OF THE INVENTION

1. Field of the Invention

The present invention relates to a display device and a manufacturing method thereof, and more particularly, to a display device and a manufacturing method thereof having a light emitting layer on a pixel electrode.

2. Description of the Related Art

An organic light emitting diode (“OLED”) has been popular because it is driven by a low voltage, is relatively thin and light, has a wide viewing angle and a relatively short response time. Such an OLED is classified into a passive matrix type and an active matrix type according to driving methods. The passive matrix type of OLED is manufactured by a relatively simple process. However, the power consumption of the passive matrix type of OLED surges as its size and resolution become larger. Thus, the passive matrix type of OLED is employed to a small-sized display, generally. Meanwhile, the active matrix type of OLED is manufactured by a relatively complicated process, while providing a large-sized screen and high resolution.

In the active matrix type of OLED, a thin film transistor is connected with respective pixel regions and controls emission of a light emitting layer according to the pixel region. Each pixel region includes a pixel electrode. Each pixel electrode is electrically disconnected from adjacent pixel electrodes so that each pixel can be driven independently. A wall is formed between the pixel regions to prevent short-circuit of the pixel regions and to divide the respective pixel regions. The wall is higher than the pixel regions, and has a rectangular shape along the side of the pixel electrode, generally.

Ink is jetted to the pixel electrode, leaving the wall therebetween. Ink has a nature of remaining round with surface tension, so that it is not properly jetted to corners of the wall which has a right or acute angle. Non-uniform ink-jetting operations cause pixel errors. Also, the pixel electrode and the common electrode are short-circuited with each other, thereby hardly transmitting a video signal.

### BRIEF SUMMARY OF THE INVENTION

Exemplary embodiments provide a display device and a manufacturing method thereof which emits light uniformly.

An exemplary embodiment of a display device includes a plurality of thin film transistors, a passivation layer formed on the thin film transistors, a pixel electrode formed on the passivation layer and including a rectangular shape and a contact region electrically connected with the thin film transistors, and a wall formed around the pixel electrode. A portion of the wall is spaced from the pixel electrode. The contact region is formed along a side of the pixel electrode.

In an exemplary embodiment, the contact region is formed on a long side of the pixel electrode.

In an exemplary embodiment, the contact region is formed on a short side of the pixel electrode.

In an exemplary embodiment, the pixel electrode includes at least one corner having a round shape.

In an exemplary embodiment, a portion of the pixel electrode exposed by the wall includes at least one corner having a round shape.

In an exemplary embodiment, the wall is formed on the contact region.

In an exemplary embodiment, the display device further includes a light emitting layer formed between the walls. A portion of the passivation layer is covered by the light emitting layer.

In an exemplary embodiment, the display device further includes a common electrode formed on the light emitting layer.

In an exemplary embodiment, the wall includes at least two layers.

In an exemplary embodiment, the wall includes a double layer. A lower layer of the wall includes an inorganic layer and an upper layer of the wall includes an organic layer.

An exemplary embodiment of a display device includes a plurality of thin film transistors, a passivation layer formed on the thin film transistors, a pixel electrode formed on the passivation layer and including a rectangular shape and a long side electrically connected with the thin film transistors, a wall formed around the pixel electrode and through which at least a portion of the passivation layer is exposed, and a light emitting layer formed between the walls.

In an exemplary embodiment, the display device further includes a contact hole formed on the passivation layer and electrically connected with the thin film transistors. The wall is formed on the contact hole.

An exemplary embodiment provides a method of manufacturing a display device. The method includes forming a plurality of thin film transistors and a passivation layer on an insulating substrate, forming a pixel electrode on the passivation layer and including a rectangular shape and a long side electrically connected with the thin film transistors, forming a wall around the pixel electrode and forming a light emitting layer between the walls. A portion of the wall is spaced from the pixel electrode

In an exemplary embodiment, the forming a light emitting layer includes an inkjet method.

### BRIEF DESCRIPTION OF THE DRAWINGS

The above and/or other aspects and advantages of the present invention will become apparent and more readily appreciated from the following description of the embodiments, taken in conjunction with the accompany drawings of which:

FIG. 1 is a schematic view of an exemplary embodiment of a display device according to the present invention;

FIG. 2 is a cross-sectional view of the display device, taken along line II-II in FIG. 1;

FIG. 3 is a cross-sectional view of the display device, taken along line III-III in FIG. 1; and

FIGS. 4A through 4C are sectional views to illustrate an exemplary embodiment of a manufacturing method of the display device according to the present invention.

### DETAILED DESCRIPTION OF THE INVENTION

Hereinafter, embodiments of the present invention will be described with reference to accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. Like numbers refer to like elements throughout. As used herein, the term “and/or” includes any and all combinations of one or more of the associated listed items.

Spatially relative terms, such as “below”, “lower”, “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “lower” relative to other elements or features would then be oriented “upper” relative to the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the present invention will be described in detail with reference to the accompanying drawings.

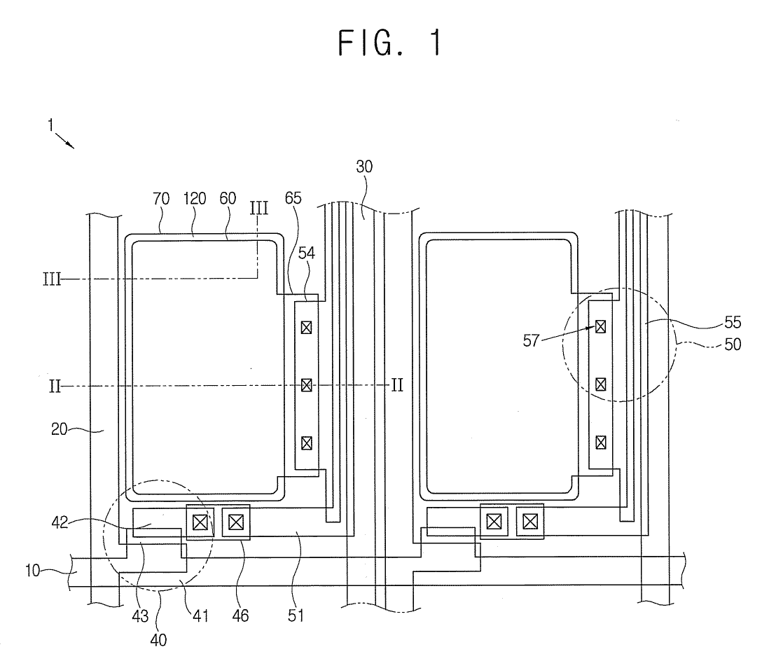

Referring to FIGS. 1 through 3, an exemplary embodiment of a display device according to the present invention will be described.

As shown therein, a display device 1 includes a gate line 10, a data line 20, a driving voltage line 30, a plurality of thin film transistors 40 and 50 which are formed on an insulating substrate 100, a passivation layer 120 which covers the thin film transistors 40 and 50, a pixel electrode 60 which is formed on the passivation layer 120 and electrically connected with the driving transistor 50 through a contact hole 57, a wall 70 which is spaced from the pixel electrode 60, a light emitting layer 80 which is exposed between walls 70 and a common electrode 90 which is formed on the light emitting layer 80.

The driving voltage line 30 is parallel to the data line 20 and substantially perpendicular to the gate line 10 to form a matrix type pixel. In exemplary embodiments, the driving voltage line 30 may include a data metal layer and may be formed on the same layer as the data line 20. The driving voltage line 30 transmits a driving voltage at a substantially regular level from the outside, to the driving transistor 50.

The thin film transistors 40 and 50 include a switching transistor 40 formed on a region where the gate line 10 and the data line 20 cross each other, and a driving transistor 50 connected with the driving voltage line 30 and the switching transistor 40.

The switching transistor 40 includes a gate electrode 41 which is a part of the gate line 10, a drain electrode 43 which is extended from the data line 20 to the pixel region and a source electrode 42 which transmits a data voltage to the driving transistor 50. A semiconductor layer (not shown) may be disposed between the gate electrode 41, and the source electrode 42 and the drain electrode 43, to form a channel area. The source electrode 42 is electrically connected with a gate electrode 51 of the driving transistor 50 through a bridge electrode 46. A contact hole is formed on the source electrode 42 of the switching transistor 40 and the gate electrode 51 of the driving transistor 50, respectively.

The driving transistor 50 includes the gate electrode 51 which is connected with the source electrode 42 of the switching transistor 40, a drain electrode 55 which is a part of the driving voltage line 30, and a source electrode 54 which is divided from the drain electrode 55 and connected with the pixel electrode 60, and a semiconductor layer (not shown) which is disposed between the drain electrode 55 and the source electrode 54, and elongated in a direction of the driving voltage line 30.

The driving transistor 50 adjusts a current between the drain electrode 55 and the source electrode 54 by a data voltage supplied to the gate electrode 51 of the driving transistor 50. A current supplied to the pixel electrode 60 is proportional to the difference between the data voltage supplied from the gate electrode 51 and the driving voltage supplied from the drain electrode 55 of the driving transistor 50.

In an exemplary embodiment, the thin film transistors 40 and 50 may include amorphous silicon, but are not limited thereto. Alternatively, the thin film transistors 40 and 50 may include polysilicon.

The pixel electrode 60 has a substantially rectangular shape when viewed on a plane as illustrated in FIG. 1. The pixel electrode 60 includes a contact region 65 which is electrically connected with the driving transistor 50. The contact region 65 includes a plurality of the contact holes 57. The contact region 65 is formed along a longitudinal side of the pixel electrode 60.

The wall 70 is considered as partitioning the pixel electrode 60. The wall 70 is spaced from the pixel electrode 60, thereby exposing the passivation layer 120 which is formed on a lower part (e.g., a lower surface) of the pixel electrode 60.

In a conventional display device, the wall overlaps the pixel electrode, thereby forming little to no light emitting material on a corner of the wall which overlaps the pixel electrode. As in the illustrated embodiment, the display device does not form the pixel electrode 60 on the corner of the wall 70, thereby limiting light from being emitted and reducing or effectively preventing the pixel error from being generated on the corner thereof. Even when the corner of the wall 70 is not completely filled with a light emitting material to cause a non-uniform light emitting layer 80, a short-circuit with the common electrode 90 is not generated due to the absence of the pixel electrode 60 on the corner.

The wall 70 is formed on the contact region 65 to cover the contact holes 57.

Further, the conventional display device, the contact region is formed on the corner of the pixel electrode to connect the pixel electrode and the drain electrode of the driving transistor. In a display device, the light emitting layer may not be properly formed on the contact region of the corner. Also, the light emitting layer may be not properly formed on the contact region connected with the driving transistor, even though the pixel electrode is spaced from the wall to enhance the light emitting efficiency. Accordingly, the portion exposed by the passivation layer may not be utilized.

As illustrated in the exemplary embodiment, the contact region 65 of the display device 1 is formed along the longitudinal side of the pixel electrode 60. In an exemplary embodiment, a light emitting ink forming the light emitting layer 80 is substantially uniformly supplied to a side of, not to the corner of the pixel electrode 60, thereby forming the contact region 65 on the side of the pixel electrode 60.

The pixel electrode 60 has a substantially rectangular shape, but the corner may be round. The wall 70 formed along the corner of the pixel electrode 60 may have a round shape. When a liquid light emitting material is dropped to or formed on the insulating substrate 100, the liquid light emitting material has a nature of forming a hemisphere shape. Thus, the corner of the pixel electrode 60 is correspondingly round to be efficiently filled with the light emitting material having a hemisphere shape.

The corners of the pixel electrode 60 and the wall 70 are round, but they are not limited thereto. Alternatively, the corners of the pixel electrode 60 and the wall 70 may be rectilinear (e.g., straight), or one of the pixel electrode 60 and the wall 70 corners may be round.

The number of the contact holes 57 formed on the contact region 65 may vary according to the size of the pixel electrode 60. In an alternative embodiment, the contact region 65 may be formed along a short (e.g., transverse) side of the pixel electrode 60.

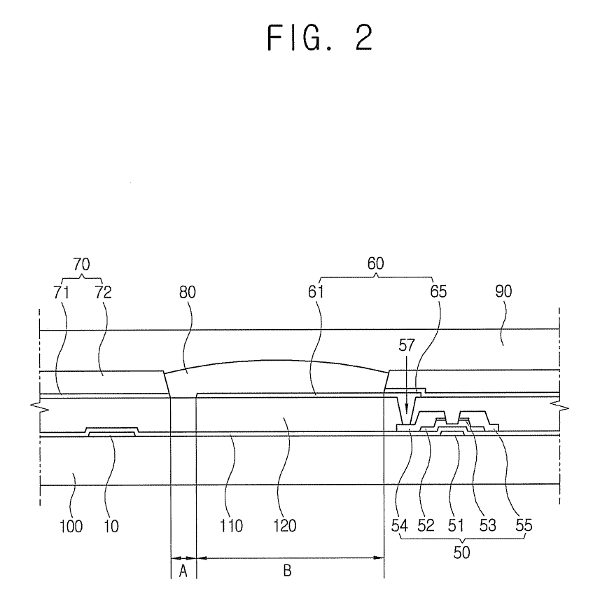

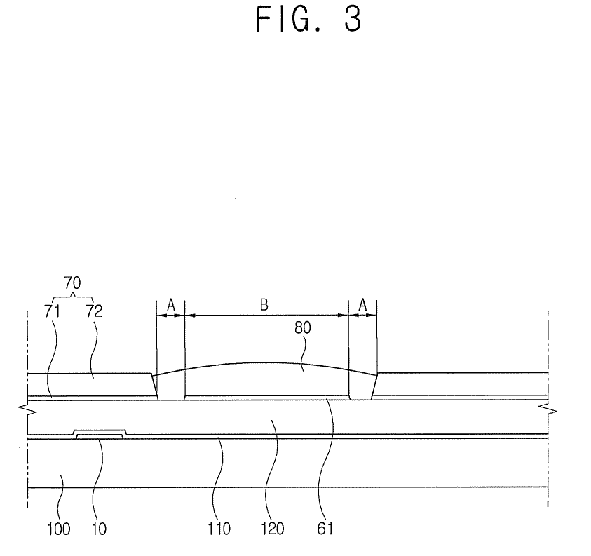

The pixel electrode 60 and the wall 70 of the illustrated embodiment will be described in detail with reference to FIGS. 2 and 3.

The gate line 10 and the gate electrode 51 of the driving transistor 50 is formed on the insulating substrate 100 which includes an insulating material such as glass, quartz, ceramic or plastic.

A gate insulating film 110, that may include, but is not limited to, silicon nitride (SiNx) is formed on the insulating substrate 100, the gate line 10 and the gate electrode 51. A semiconductor layer 52, such as including amorphous silicon, and an ohmic contact layer 53, such as including n+ amorphous silicon hydride highly doped with an n-type dopant, are sequentially formed on the gate insulating film 110 in a location or position corresponding to the gate electrode 51. The ohmic contact layer 53 is separated into two parts with respect to the gate electrode 51.

The source electrode 54 and the drain electrode 55 are formed on the ohmic contact layer 53 (e.g., on the two parts) and the gate insulating film 110. The source electrode 54 and the drain electrode 55 are separated with respect to the gate electrode 51.

The passivation layer 120 is formed on the source electrode 54, the drain electrode 55 and the semiconductor layer 52 exposed between the source and drain electrodes 54 and 55. In an exemplary embodiment, the passivation layer 120 may include, but is not limited to, silicon nitride (SiNₓ) and/or an organic layer. The contact holes 57 are formed on the passivation layer 120, thereby exposing an upper surface of the drain electrode 54.

The pixel electrode 60 having a substantially rectangular shape is formed on the passivation layer 120. The pixel electrode 60 may be hereinafter referred to as an anode, and supplies a hole to the light emitting layer 80. In an exemplary embodiment, the pixel electrode 60 includes a transparent conductive material such as indium tin oxide (“ITO”) or indium zinc oxide (“IZO”).

The wall 70 is formed along the side of each pixel electrode 60, and at least a portion of the wall 70 is spaced from the pixel electrode 60. The pixel electrode 60 includes a light emitting region 61 which is disposed on a lower part (e.g., lower surface) of the light emitting layer 80, and the contact region 65 connecting the driving transistor 50 and the pixel electrode 60 electrically. The wall 70 reduces or effectively prevents a short-circuit between the pixel electrodes 60 and defines the pixel region.

Referring to FIG. 2, the pixel region includes a non-light emitting region A which exposes the passivation layer 120 and a light emitting region B which emits light. The wall 70 covers the contact region 65 which is formed on the contact holes 57 connecting the driving transistor 50 and the pixel electrode 60 electrically.

The wall 70 as illustrated in FIGS. 2 and 3 includes two layers 71 and 72, but is not limited thereto. Alternatively, the wall 70 may include more than two payers, such as a multi-layer structure. A lower layer 71 of the wall 70 may include an inorganic layer, such as silicon oxide (SiO₂). An upper layer 72 of the wall 70 may include an organic layer. The wall 70 is hydrophobic as the upper layer 72 including the organic material occupies most of the wall 70. Thus, even when the light emitting material, which is hydrophilic, is jetted to the wall 70, the light emitting material may easily move to the pixel electrode 60 due to the hydrophobic nature of the wall 70. The hyrdrophobic nature of the wall 70 may cause pixel errors as the light emitting material is not completely formed on the corner of the wall 70 and the light emitting layer 80 is not uniform.

As shown in FIG. 1, the wall 70 of the display device 1 is spaced from the pixel electrode 60 with a predetermined distance. The pixel region which is exposed by the wall 70 has a rectangular shape. The wall 70 is disposed along the side of the pixel electrode 60. A portion of the wall that does not overlap the pixel electrode 60 exposes the passivation layer 120.

The light emitting layer 80 is formed on the pixel region between the walls 70. The upper areas of the driving transistor 50 and the contact hole 57 are covered by the walls 70 as shown in FIG. 2, but the pixel electrode 60 in the opposite side is spaced from the wall 70. As the pixel electrode 60 is spaced from the wall 70, the passivation layer 120 formed below the pixel electrode 60 is exposed. The light emitting layer 80 is formed on the exposed portion of the passivation layer 120. The light emitting region B of the pixel electrode 60 on which the wall 70 is not formed, emits light. The exposed portion of the passivation layer 120 includes the non-light emitting region A.

As shown in FIG. 3, opposite ends of the light emitting layer region 61 of the pixel electrode 60 (e.g., at longitudinal ends) are spaced from the wall 70. The light emitting layer 80 which is formed on the light emitting layer region 61 alone emits light at light emitting region B. A portion of the light emitting layer 80 which exposes the passivation layer 120 and where the pixel electrode 60 is not formed includes the non-light emitting region A. The hole is supplied thereto, even when the light emitting layer 80 is formed between the walls 70.

The interval of the non-light emitting region A by which the pixel electrode 60 is spaced from the wall 70 may vary according to a processing margin and/or required opening ratio. The interval between the pixel electrode 60 and the wall 70 may be different at a short (e.g. transverse) or long (e.g., longitudinal) side thereof in consideration of relations between wires (not shown) which are adjacent to the pixel electrode 60.

The light emitting layer 80 is formed between the walls 70. The hole transmitted from the pixel electrode 60 is combined with an electron supplied from the common electrode 90 on the light emitting layer 80, thereby generating an exciton and emitting light during a non-activation process of the exciton. The light emitting layer 80 may include polymer and may emit blue, red and/or green light.

The common electrode 90 is disposed on the light emitting layer 80. The common electrode 90 supplies an electron to the light emitting layer 80. The common electrode 90 may include, but is not limited to, an opaque material such as aluminum. Light which is emitted from the light emitting layer 80 is directed to the insulating substrate 100, which is called a bottom emission method.

In exemplary embodiments, the display apparatus 1 may further include a hole injection layer (not shown) and a hole transfer layer (not shown) between the pixel electrode 60 and the light emitting layer 80, and an electron transfer layer (not shown) and an electron injection layer (not shown) which are disposed between the light emitting layer 80 and the common electrode 90. In an exemplary embodiment, the display apparatus 1 may further include a capping member which reduces or prevents moisture and air from being introduced to the passivation layer 120 passivating the common electrode 90 and to the light emitting layer 80.

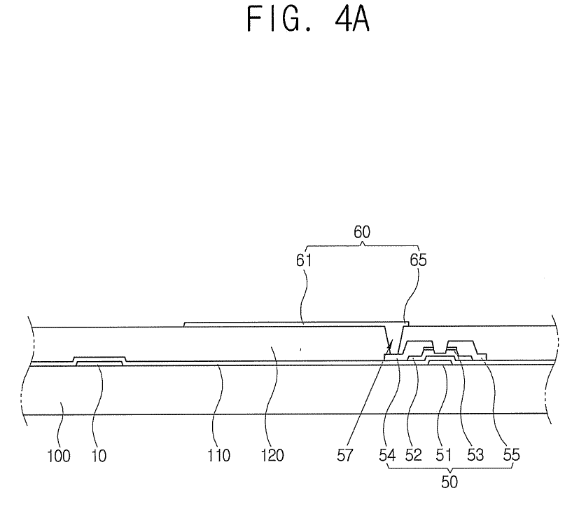

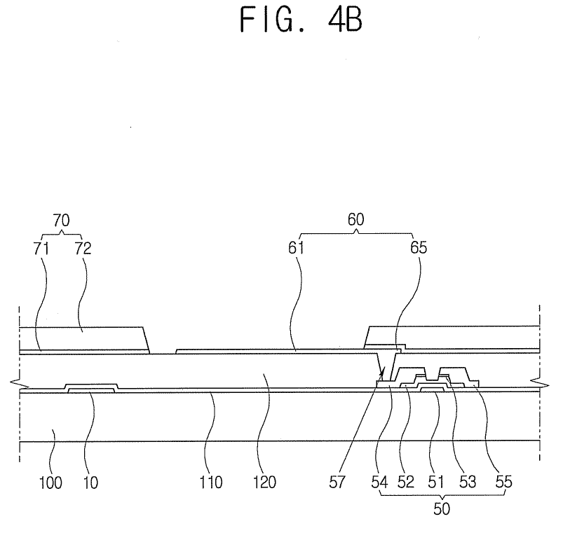

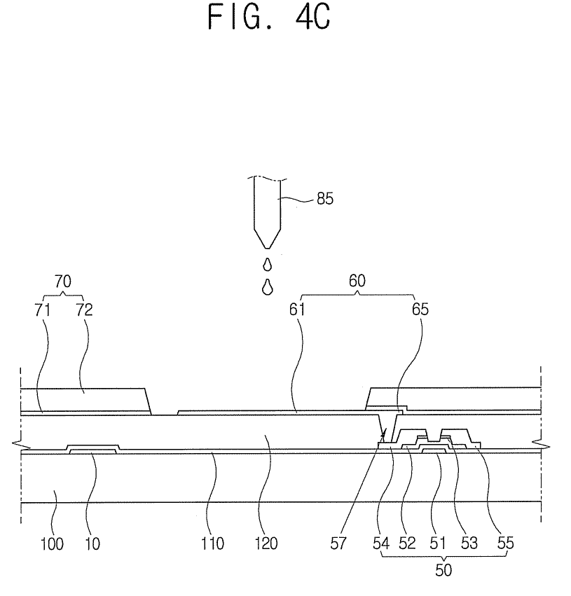

FIGS. 4A through 4C are cross-sectional views to illustrate an exemplary embodiment of a manufacturing method of the display device 1 according to the present invention.

As shown in FIG. 4A, the gate line 10 and the driving transistor 50 are formed on the insulating substrate 100. The channel of the driving transistor 50 includes amorphous silicon, and may be manufactured by any of a number of methods suitable for the purpose described herein.

After the driving transistor 50 is formed, the passivation layer 120 is formed on the driving transistor 50. In an exemplary embodiment, when the passivation layer 120 includes silicon nitride (SiNx), a chemical vapor deposition (“CVD”) may be used to form the passivation layer 120. The passivation layer 120 is processed by photolithography to form the contact holes 57 through which the source electrode 54 is exposed.

After the contact holes 57 are formed, the pixel electrode 60 which is connected with the source electrode 54 through the contact holes 57 is formed. The pixel electrode 60 may be formed by depositing indium tin oxide (“ITO”) through a sputtering method and patterning it. The pixel electrode 60 may be called an anode electrode since it supplies the hole to the light emitting layer 80.

As shown in FIG. 4B, the wall 70 is formed between pixel electrodes 60 that are adjacent to each other. As in the illustrated embodiment, the wall 70 includes a double layer. The lower layer 71 of the wall 70 may include an inorganic layer including SiO₂, and the upper layer 72 of the wall 70 may include an organic layer. In an alternative exemplary embodiment, the wall 70 may include at least two layers and formed by deposition and photolithography of a layer-forming material.

The wall 70 decreases in size (e.g., a distance taken in a direction parallel to the insulating substrate 100) from a bottom (e.g., lower portion) to a top (e.g., an upper portion). A side of the wall 70 may be inclined from the lower portion to the upper portion. The wall 70 is formed on the driving transistor 50 and the contact region 65.

As shown in FIG. 4C, the light emitting layer 80 is formed on the pixel electrode 60 in an area that is not covered by the wall 70 and on the exposed portion of the passivation layer 120. The light emitting layer 80 directly contacts the exposed portion of the passivation layer 120. As shown in the illustrated exemplary embodiment, the light emitting layer 80 is formed by an inkjet method in which ink is supplied through a nozzle 85. The nozzle 85 applies the light emitting ink on a predetermined position while moving on the insulating substrate 100. The display device 1 may further include a controller (not shown) which controls the nozzle 85 to move and to apply ink.

In exemplary embodiments, the light emitting layer 80 may be formed through a nozzle coating or a spin coating method by dissolving ink through a solvent.

The common electrode 90 is formed on the light emitting layer 80 to finish the display device 1 as shown in FIG. 2.

As described above, the present invention provides a display device and a manufacturing method thereof which emits light uniformly.

Although a few embodiments of the present invention have been shown and described, it will be appreciated by those skilled in the art that changes may be made in these embodiments without departing from the principles and spirit of the invention, the scope of which is defined in the appended claims and their equivalents.

What is claimed is:

1. A display device comprising:
a plurality of thin film transistors;
a passivation layer formed on the thin film transistors;
a pixel electrode disposed on the passivation layer and including a rectangular shape and a contact region electrically connected with the thin film transistors; and
a wall formed around the pixel electrode, a portion of the wall spaced from the pixel electrode,
wherein the contact region is formed along a side of the pixel electrode.

2. The display device according to claim 1, wherein the contact region is formed on a long side of the pixel electrode.

3. The display device according to claim 1, wherein the contact region is formed on a short side of the pixel electrode.

4. The display device according to claim 3, wherein the pixel electrode includes at least one corner having a round shape.

5. The display device according to claim 3, wherein a portion of the pixel electrode exposed by the wall includes at least one corner having a round shape.

6. The display device according to claim 1, wherein the wall is formed on the contact region.

7. The display device according to claim 1, further comprising:
a light emitting layer formed between the walls, wherein
a portion of the passivation layer is contacted by the light emitting layer.

8. The display device according to claim 7, further comprising:
a common electrode formed on the light emitting layer.

9. The display device according to claim 1, wherein the wall comprises at least two layers.

10. The display device according to claim 9, wherein the wall comprises a double layer including a lower layer comprising an inorganic layer and an upper layer comprising an organic layer.

11. The display device according to claim 1, wherein the pixel electrode includes at least one corner having a round shape in a plane view.

12. The display device according to claim 1, wherein a portion of the pixel electrode exposed by the wall includes at least one corner having a round shape.

13. The display device according to claim 2, wherein the pixel electrode includes a corner having a round shape.

14. The display device according to claim 2, wherein a portion of the pixel electrode is exposed by the wall includes a corner having a round shape.

15. A display device comprising:
a plurality of thin film transistors;
a passivation layer formed on the thin film transistors;
a pixel electrode disposed on the passivation layer and including a rectangular shape and a long side electrically connected with the thin film transistors
a wall disposed around the pixel electrode and through which at least a portion of the passivation layer is exposed; and
a light emitting layer formed between the walls.

16. The display device according to claim 15, further comprising:
a contact hole formed on the passivation layer and electrically connected with the thin film transistors, wherein
the wall is formed on the contact hole.

17. A method of manufacturing a display device, the method comprising:
forming a plurality of thin film transistors and a passivation layer on an insulating substrate;
forming a pixel electrode on the passivation layer, the pixel electrode including a rectangular shape and a long side electrically connected with the thin film transistors;
forming a wall around the pixel electrode, at least a portion of the wall is spaced from the pixel electrode; and
forming a light emitting layer between the walls.

18. The method according to claim 17, wherein the forming
a light emitting layer includes an inkjet method.
